(19) United States
(12) Patent Application Publication
(10) Pub. No.: US 2007/0205491 A1
(43) Pub. Date: Sep. 6, 2007

(54) Insulating material

(76) Inventor: Steve Tew, Oxfordshire (GB)

Correspondence Address: WENDEROTH, LIND & PONACK, L.L.P., 2033 K STREET N. W., SUITE 800, WASHINGTON, DC, 20006-1021, US

(21) Appl. No.: 11/797,471

(22) Filed: May 3, 2007

Related U.S. Application Data
(63) Continuation-in-part of application No. PCT/GB05/50200, filed on Nov. 8, 2005.

(30) Foreign Application Priority Data
Nov. 8, 2004 (GB) 0424531.2
Jan. 17, 2005 (GB) 0500740.6
Feb. 8, 2005 (GB) 0502474.0

(51) Int. Cl. H01L 23/58

(52) U.S. Cl. 257/632

(57) ABSTRACT

An insulating material comprising a multiplicity of highly porous particles embedded within a matrix material, the pores within the particles being substantially evacuated.

The present invention relates to materials, and in particular though not necessarily to glass, ceramics, metal and rubber based materials, suitable for use in the manufacture of containers such as drinks containers and for use in food packaging, insulated clothing, medical containers, cooking utensils, beer glasses, window panes, building insulation, and metal construction.

A problem with many materials used in the manufacture of articles such as those listed in the preceding paragraph is that they are not particularly insulating. A high degree of insulation may be desirable, for example, in the case of a drinks container. After removal from a cold storage environment, the temperature of the liquid within the container will start to rise due to heat transfer with the external environment. The problem is particularly acute in the case of metallic containers as the metal walls conduct heat rapidly into the interior space.

Metallic beverage cans having improved thermal insulating properties are known in the prior art. For example JP3254322 describes a dual wall construction can body, the space between the two tubes being either evacuated or filled with a heat insulating material. U.S. Pat. No. 6,474,498 describes a container having an outer can and an inner liner of “bubble wrap” material. However, these known containers suffer from a number of disadvantages including; high cost, insufficient thermal insulation, poor recycleability, difficulty of manufacture, and an inability to cope with a pressurised content.

An insulating material is known from WO98/07780 and DE69819365T2 which comprises particles of aerogel embedded within a plastics matrix for molding as an insert or for spray coating.

According to a first aspect of the present invention there is provided an insulating material comprising a multiplicity of highly porous particles embedded within a matrix material, the pores within the particles being substantially evacuated.

According to a second aspect of the of the present invention there is provided a method of manufacturing an insulating material, the method comprising introducing a multiplicity of highly porous particles into a softened or molten matrix material within a substantially evacuated atmosphere, and allowing the matrix material to harden or solidify about the particles.

According to a third aspect of the present invention there is provided a method of manufacturing an insulating material, the method comprising substantially evacuating the spaces within particles of a highly porous material, coating the evacuated particles with a non-porous material, and embedding a multiplicity of the coated particles within a matrix material.

According to a fourth aspect of the present invention there is provided a method of manufacturing an insulating material, the method comprising substantially evacuating the spaces within particles of a highly porous material, coating the evacuated particles with a non-porous material, and embedding a multiplicity of the coated particles within a matrix material.

According to a fifth aspect of the present invention there is provided a beverage container comprising an outer substantially rigid wall and a base, and a gas releasing mechanism located within the container adjacent to the base, the gas releasing mechanism being formed integrally with a container insulating wall or walls which are located adjacent to the inner surface of said rigid wall and which provide insulation for the contents of the container.

For a better understanding of the present invention and to show how the same may be carried into effect, reference will be made by way of example to the accompanying drawings, in which:

FIG. 1 illustrates a system for producing a thermally insulating material;

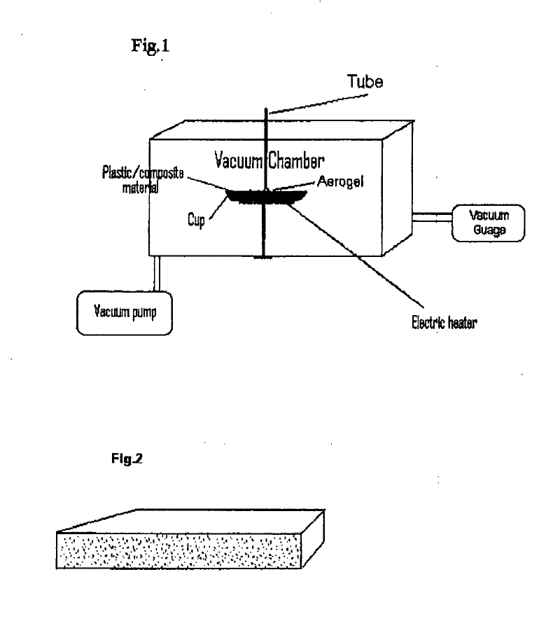

FIG. 2 shows a cross-sectional view of a thermally insulating material;

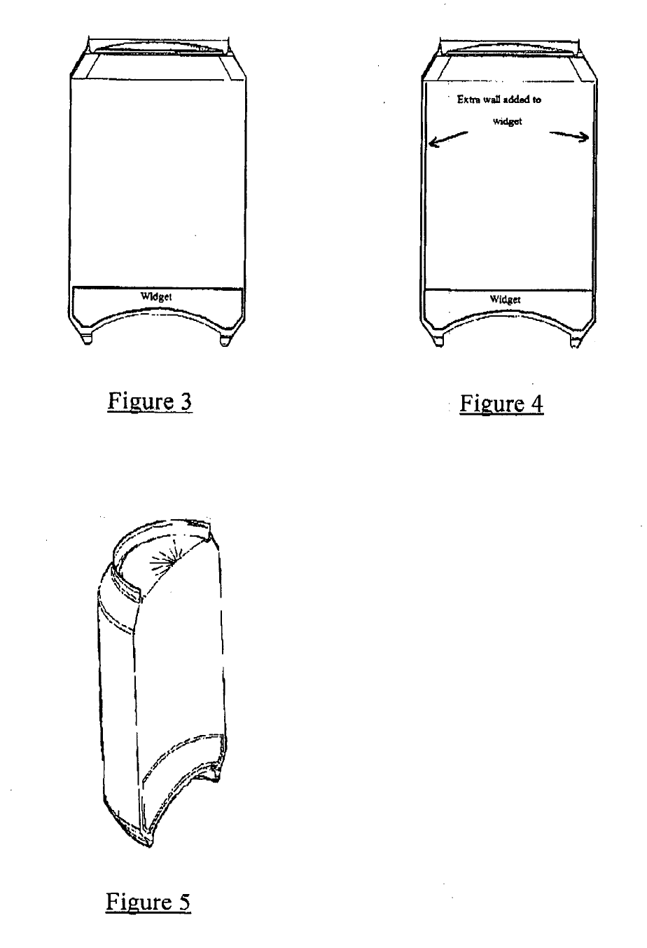

FIG. 3 shows a vertical cross-section through a conventional drinks can incorporating a widget;

FIG. 4 shows a vertical cross-section through an improved can incorporating a widget; and

FIG. 5 shows a cross-sectional perspective view of the improved can of FIG. 4.

An insulating material will now be described which exhibits an extremely high degree of thermal insulation while at the same time being flexible, in terms of its uses, is extremely lightweight, and remains stable for prolonged periods.

This material may be produced by introducing particles of a hydrophobic, open cell thermo insulating material into a molten matrix forming material. This process is carried out under vacuum, such that air is removed from the open cell material particles during the process. Some means is provided for producing a relatively uniform distribution of the particles in the matrix material. The matrix material is allowed to set, possibly in a vacuum or possibly in an air atmosphere (as the evacuated particles are embedded within the matrix material, air should not diffuse through the matrix material during the setting process), so that the evacuated particles are embedded within the set material. The insulating and sound absorbing properties can be increased in proportion to the density of the particles within the matrix. For example, introducing 5% by volume of particles into the matrix will result in a relatively small increase in the thermal insulating property of the material, whilst introducing 85% by volume will result in a significant increase. The amount of particles which may be limited by the structural integrity of the resulting composite material.

The production process outlined here ensures that vacuum formed within the highly porous structure of the hydrophobic filling material, which is responsible for low heat conductivity, is maintained following manufacture of the insulating material.

A possible candidate material for incorporation into the matrix material is that known as “aerogel” which comprise interconnected strands of silica. Aerogels are very interesting materials due to their extremely low density, low index of refraction, and reasonably high light transmission properties. The density of an aerogel can be less than 1% of that of ordinary glass, with aerogels still exhibiting glass-like transparency and high monolithicity. Aerogels can withstand temperatures in excess of 750 degrees Celsius, which exceeds the melting point of many suitable matrix materials. Cabot Corporation (USA) manufactures and distributes an aerogel material under the trade mark Nanogel™. Explained simply, the aerogel production process consists of a sol-gel process followed by a supercritical drying of the gel. The product is a transparent, highly porous, inorganic material in which the solid part is quartz.

The matrix material may be a metal or metal alloy, for example aluminum. The incorporation of evacuated monolithic silica aerogel to boost the thermal insulating properties of a metal such as aluminum is one of the most promising ways to produce a material for use in the production of containers which are both highly insulating and highly lightweight. This would give clear benefits to say a drinks container in that the contents could be maintained at or near a given temperature for prolonged periods.

Considering further the production process, reference is made to FIG. 1. Aluminum in powder form is placed in a tray or mould, within a vacuum chamber. The powder is heated (e.g. using an electric heater) to a temperature in excess of the melting point of aluminum, in excess of 660 degrees celsius. This temperature is well below the melting point of aerogel material. The chamber is evacuated, and the aerogel particles introduced into the molten metal by means of a spray tube and some suitable air interlock. Some means may be provided in the tray supporting the metal material for evenly disbursing the aerogel within the molten material, e.g. a rotating paddle. The molten aluminum is allowed to cool in the vacuum with the thermo insulating filling material inside, the aluminum forming a protective seal around the aerogel particles as it solidifies. [If the material were allowed to cool within an air atmosphere, the evacuated aerogel particles may be crushed due to the high outside pressure.] The result is a lightweight aluminum composite material with very low thermal conductivity. FIG. 2 illustrates a cross sectional cut into the cooled composite material.

The tray within which the aluminum is melted may be the shape of the final product. Alternatively, the process may produce a block of material which is subsequently remolded into a final shape, rolled out as a sheet, etc.

A suitable plastics matrix material for use with the process described here is polyethylene terephthalate (PET). The production process may be similar to that described above, although the powder used to form the matrix need only be heated to around 246-260 degrees celsius.

Other suitable matrix materials are synthetic rubber materials such as latex. The incorporation of evacuated monolithic silica aerogel to boost the thermal insulating properties of a rubber material such as latex is one of the most promising ways to produce a material for use in the production of clothing, such as jackets, gloves and hats, which is highly insulating.

A suitable glass matrix material for use with the process described here are glasses such as soda glass. The softening point of soda glass is in the region of 695 degrees Celsius, which is again well below the melting point of aerogel.

In a particular embodiment of the invention, a beverage container is produced having an outer metallic can, having the appearance of a conventional carbonated drinks can. The can is provided with an inner lining made of a plastics insulating material as described above. Any space between the inner and outer walls is sealed to prevent ingress of liquid into this space.

An extension of this embodiment would be to combine the insulating walls with a “widget” of the type used in canned beverages to release nitrogen into the beverage as described in U.S. Pat. No. 4,832,968. Conventional widgets have the shape of a short cylinder which sits in the base of the can. By manufacturing the widget from a composite plastics material as described here, and providing a cylindrical tube extending upward from the widget base which fits snugly within the can, an insulating can, can be produced without the addition of any further production step. This structure has the additional advantage that it provides support for the can walls, allowing the walls to be thinner, saving metal (the metal cost is significant in terms of the overall manufacturing cost). This improved can design is illustrated in FIGS. 3 to 5.

The can design may be improved by forming a spiral or any other type of groove on the outside wall of the new widget in order to allow the can to be more easily crushed. Such a groove would also facilitate the release of air from beneath the widget as the widget is pushed into the can.

The person of skill in the art will appreciate that various modifications may be made to the above described embodiment without departing from the scope of the present invention. For example, a process may be developed for coating aerogel beads or balls, in a vacuum chamber, with a thin metal (or plastics or other material) coating, e.g. using a metal evaporation process, the coating being sufficient to stop the vacuum inside the ball collapsing once the particles are removed from the vacuum chamber. In one example manufacturing process, the beads are coated whilst being tumbled within a rotating drum, the inside of which is evacuated. In order to ensure uniformity of bead size, the beads may be sorted, before or after coated, by filtering with a sieve. The beads described here may subsequently be used to manufacture an insulating material or a product. The beads may be employed loose, or embedded within a matrix material. An example use of such a material in loft insulation or cavity insulation.

Beads of the type described in the preceding paragraph may be incorporated into a sheet (with a binding matrix material) for use in decorating or applications where heat/fire protection is required, the sheet being adhered to a wall or ceiling (e.g. with a larve and plaster finish) using a suitable adhesive. The sheet may be approximately 1 mm thick, and could be sold in rolls. As well as heat/fire protection, such a material may improve sound proofing. The sheet may be attached to a sheet of fibreglass, or sandwiched between two such sheets, to provide additional strength and/or a smooth surface for painting. Alternatively, such a sheet may be formed by adhering coated or uncoated aerogel particles to a base sheet using an electrostatic charging mechanism, magnetism or adhesive, or placed between two sheets.

In another embodiment of the invention, coated beads of the type described above may be mixed into a paint or adhesive, sold in liquid form. The material can them be painted onto a surface which, when dry, benefits from improved heat and fire resistance.

Such coated particles may also be incorporated into a porous matrix material. One such material is an extruded PTFE having a nodes and fibril structure which is porous to water vapour whilst being impermeable to water liquid. Such material is manufactured by Gore-Tex® (USA). An insulating material as described would provide an excellent fabric for clothing. This material may also prove ideal for manufacturing insoles for shoes and boots. Indeed, even where the matrix is non-porous, the insulating material may be used in the manufacture of shoe soles so as to provide highly insulating footwear.

Coated particles may also be incorporated into a fine nylon-type material wound onto reels or drums. The resulting thread can then be woven into a fabric.

1. An insulating material comprising a multiplicity of highly porous particles embedded within a matrix material, the pores within the particles being substantially evacuated.

2. A material according to claim 1, the matrix material being non-porous and substantially airtight.

3. A material according to claim 1, the matrix material being PET.

4. A material according to claim 1, said particles being coated with a non-porous airtight material, and the matrix material being porous.

5. A material according to claim 1, the matrix material being extruded PTFE.

6. A material according to any one of the preceding claims, the material being formed as a sheet.

7. A material according to any one of the preceding claims, the material being formed or spun into a thread.

8. A method of manufacturing an insulating material, the method comprising introducing a multiplicity of highly porous particles into a softened or molten matrix material within a substantially evacuated atmosphere, and allowing the matrix material to harden or solidify about the particles.

9. A method of manufacturing an insulating material, the method comprising substantially evacuating the spaces within particles of a highly porous material, coating the evacuated particles with a non-porous material, and embedding a multiplicity of the coated particles within a matrix material.

10. A sheet suitable for decorating the walls or ceilings of a building, the sheet comprising particles of a highly porous material.

11. A sheet according to claim 10, the sheet comprising a material according to any one of claims 1 to 7.

12. A sheet according to claim 10 or 11, the sheet comprising at least one fibreglass layer bonded to a layer comprising the highly porous material.

13. A beverage container comprising an outer substantially rigid wall and a base, and a gas releasing mechanism located within the container adjacent to the base, the gas releasing mechanism being formed integrally with a container insulating wall or walls which are located adjacent to the inner surface of said rigid wall and which provide insulation for the contents of the container.

14. A container according to claim 13, the gas releasing mechanism and integral insulating wall(s) being of PET.

15. A container according to claim 13 or 14, the outermost surface of the insulating wall(s) being in contact with the inner surface of the rigid wall.

16. A container according to claim 1, a sealed space being provided between the outermost surface of the insulating walls and the innermost surface of the rigid wall.

17. A container according to any one of claims 13 to 16, there being provided a pair of coaxial, spaced apart insulating walls, the space between the walls being substantially evacuated or gas filled.

18. A container according to any one of claims 13 to 17, the gas releasing mechanism and the insulating walls being formed of a material according to any one of claims 1 to 6.
